(19) United States
(12) Patent Application Publication
(10) Pub. No.: US 2010/0166942 A1
(43) Pub. Date: Jul. 1, 2010

(54) Method for Searching Parameter Codes of a Biosensor and Method for Producing a Biosensor Chip Matching a Biosensor

(76) Inventor: Chia-Nan WANG, Chiayi City (TW)

Correspondence Address: Dr. BANGER SHIA;Patent Office of Bang Shia, 102 Lindencrest Ct., Sugar Land, TX, 77479-5201, US

(21) Appl. No.: 12/345,553

(22) Filed: Dec. 29, 2008

(51) Int. Cl. G06F 19/00; G01N 27/327; G01N 27/26; C23C 16/52

(52) U.S. Cl. 427/8; 702/123

(57) ABSTRACT

A method for searching parameter codes of a biosensor and a method for producing a biosensor chip matching a biosensor, which utilize parameter codes to produce a biosensor which is applicable to the biosensor chips of different brands and a biosensor chip which is applicable to the biosensors of different brands.

### BACKGROUND OF THE INVENTION

1. Field of the Invention

The present invention relates to a method for testing and analyzing material by detecting the chemical and physical properties of the material, and more particularly to a method for searching parameter codes of a biosensor of a biosensor and a method for producing a biosensor chip matching a biosensor.

2. Description of the Prior Art

The existing biosensor chips on the market are only applicable to the biosensors from the same factory of the above biosensor chips, because different factories provide different parameters. The factories are very familiar with their respective parameters in such a manner that they can set the parameters to be sensed by the corresponding biosensors exactly. Therefore, generally speaking, the biosensor chips produced by one factory are impossibly applicable to the biosensors of other factories.

Further, since it is difficult to control the process of producing the biosensor chips and the biosensors precisely, there is sometimes a small difference between the measurement results of the same brand biosensor chips or biosensors that are produced in the different periods. Therefore, when the biosensor chips are produced by the same producer, it is necessary to cooperate the biosensors with different parameter codes (such as slope, intercept, magnification ratio, etc) to correct the calculation results. That is why the biosensor needs setting different parameter codes when the same brand biosensor chips which are produced in the different periods are used. What's more, the difference between the measurement results of the different brands of biosensors or biosensor chips is much large, so that the same brand biosensors only cooperate with their respective brand biosensor chips. As compared to the difference between the biosensors chips produced by the same producer, the difference between biosensors chips produced by the different factories having different production processes, steps, prescriptions and operators is much larger. Therefore, as for the different brands of biosensors, even if the parameter codes are adjusted, they still cannot cooperate with the different brands of biosensor chips, thus causing much inconvenience in using and purchasing and the increase of the purchase cost.

The present invention has arisen to mitigate and/or obviate the afore-described disadvantages.

### SUMMARY OF THE INVENTION

The primary objective of the present invention is to provide a method for searching parameter codes of a biosensor and a method for producing a biosensor chip matching a biosensor, which can be used to produce a biosensor which is applicable to the biosensor chips of different brands and a biosensor chip which is applicable to the biosensors of different brands.

In order to achieve the above objective, the method for searching parameter codes of a biosensor in accordance with the present invention comprises the steps of: A. selecting parameter code: selecting any specific parameter code in the biosensor; B. searching a relationship between the parameter codes: dividing a detection range into plural sections, and then performing a sample test to existing biosensor chips and using a forecast technology to find the relationship between the parameter codes; and C. testing parameter code: selecting another parameter code in the biosensor, and repeating the above steps A-B until the parameter codes in the biosensor all have been tested or the specific parameter codes have been tested.

The method for producing a biosensor chip matching a biosensor in accordance with the present invention comprises the steps of: A. searching a relationship between parameter codes of a biosensor; B. preparing enzyme and electrode: preparing a buffer solution, adding interferent and enzyme in, and preparing working electrodes according to the ingredient proportion of the reference electrodes and testing the working electrodes to enable the oxidation-reduction between the working electrodes to be detected exactly to check repeatability and linearity; C. preparing biosensor chip: fixing the above components on a biosensor chip; and D. testing and setting parameter codes: setting a sample test group number for performing the sample test operations successively to find their relationship, and comparing with the relationship found in the method for searching parameter codes of a biosensor to find out a corresponding parameter code, if no corresponding parameter code is fund, the previous steps will be repeated until the corresponding parameter code is found.

Further analysis on the abovementioned shows that the present invention can improve the convenience in using and save the purchase cost.

### BRIEF DESCRIPTION OF THE DRAWINGS

FIG. 1 is a flow chart of a method for searching parameter codes of a biosensor in accordance with the present invention;

FIG. 2 is a flow chart of a method for producing a biosensor chip matching a biosensor in accordance with the present invention.

FIG. 3 is an EGA diagram of the respective parameter codes in accordance with the present invention; and

FIG. 4 is an EGA diagram of the biosensor chips of the brand X and the self-made biosensor chips in accordance with the present invention.

### DETAILED DESCRIPTION OF THE PREFERRED EMBODIMENTS

The present invention will be clearer from the following description when viewed together with the accompanying drawings, which show, for purpose of illustrations only, the preferred embodiment in accordance with the present invention.

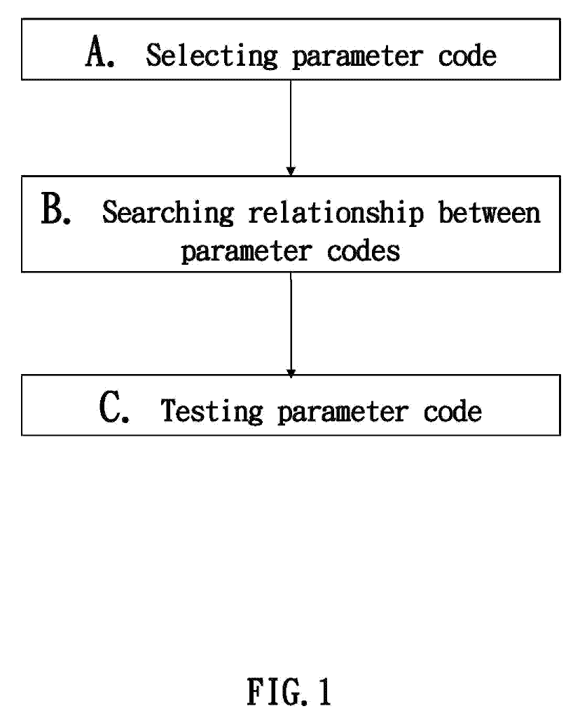

Referring to FIGS. 1, a method for searching parameter codes of a biosensor in accordance with a preferred embodiment of the present invention comprises the steps of:

A. Selecting parameter code: selecting any specific parameter code in the biosensor, if the biosensor doesn't have any parameter codes, it represents that this biosensor is a single parameter code type machine, so election is unneeded;

B. Searching relationship between parameter codes: dividing the measurement range into plural sections (at least two sections, the more the sections are, the better the effect will be), and then performing a sample test to biosensor chips of a certain brand X and using the forecast technology to find the relationship between the parameter codes, the forecast technology can be:

1. statistical technologies such as linear regression, non-linear regression and non-parameter regression;

2. evolutionary computation or soft computing technologies such as neural network, fuzzy theory and genetic algorithm; and

3. grey theory. Nevertheless, in most practices, the linear regression technology is capable of finding the relationship properly, but in such a condition, from the theoretical angle, the grey theory technology is much better;

C. Testing parameter code: selecting another specific parameter code in the biosensor, and repeating the steps A-B until the parameter codes in the biosensor all have been tested or the specific parameter codes have been tested.

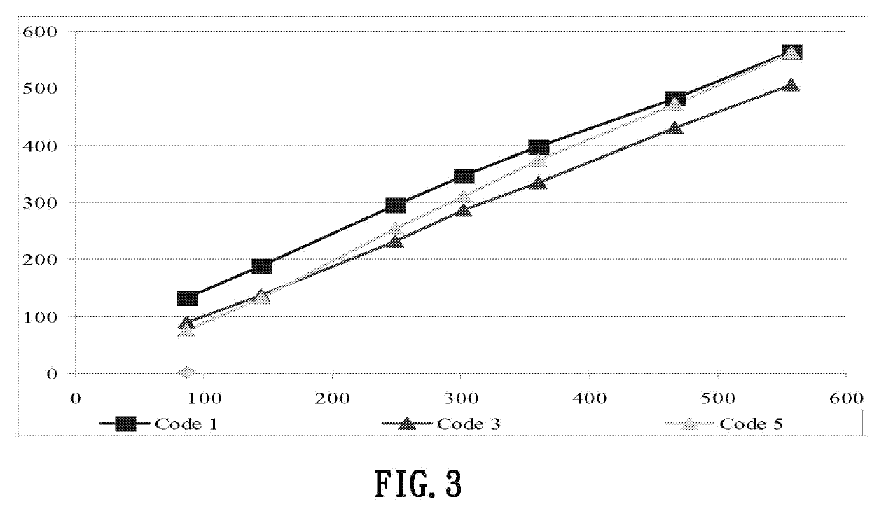

Finally, referring to FIG. 3 (the unit of transversal axis is expressed in mg/dL, and the unit of longitudinal axis is expressed in mg/dL), the relationship of the respective parameter codes can be obtained based on error grid analysis.

After the parameter codes of a biosensor are found by the above method, the biosensor parameter codes can be used to produce a biosensor chip matching the biosensor.

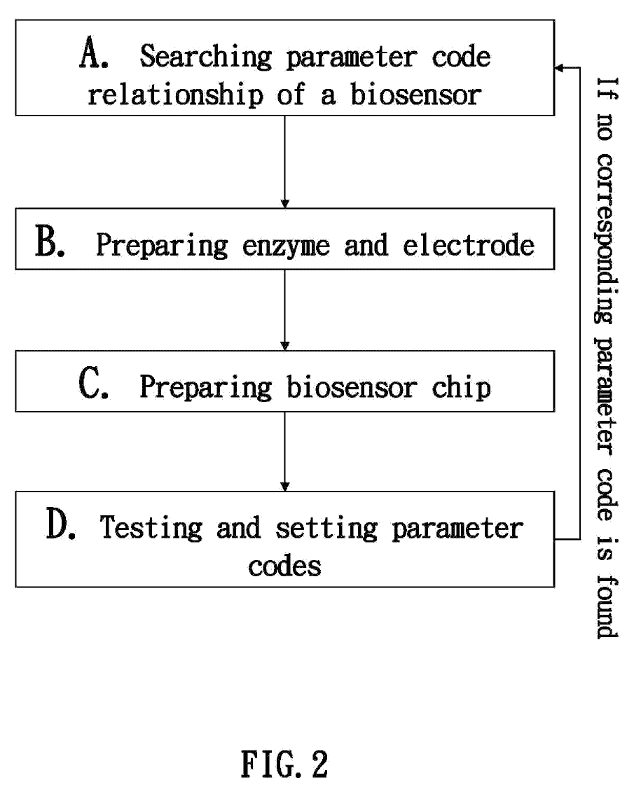

Referring to FIG. 2, a method for producing a biosensor chip matching a biosensor in accordance with a preferred embodiment of the present invention comprises the following steps:

A. Searching parameter code relationship of a biosensor;

B. Preparing enzyme and electrode: preparing a buffer solution, adding in anti-interference and enzyme, and preparing working electrodes according to the ingredient proportion of the reference electrodes and testing the working electrodes to enable the oxidation-reduction between the electrodes to be detected exactly to check the repeatability and linearity, and this step is described in detail as follows:

1. Preparing buffer solution (the buffer solution can maintain a nearly constant PH if it is diluted or if strong acids or bases are added): for example, using H2C8H4O4-KHC8H4O4 and H3BO3-Na2B4O7 to prepare the buffer solution with the PH value ranging from 3.6-8.0 according to the working electrodes;

2. Adding in anti-interference such as Poly-N-Vinyl Pyrrolidone (PVP), Polyvinyl Alcohol (PVA), Cellulose, and etc, and the content of the anti-interference ranges from 0.5% to 10% so as to stabilize the measurement signals of the biosensor chips, according to the parameter codes and electrode characteristic, adding in electronic mediator with the content ranging from 3%-40% to utilize the electronic mediator to increase the electron transmit speed and reduce the over-voltage, so that the above substances can be subjected to the oxidation-reduction reaction at a relatively low potential, and the oxidation-reduction reaction can be detected by the electrodes, thus greatly increasing the electrode surface selectivity and sensitivity;

3. Preparing the enzyme according to the parameter codes of the biosensor and the electrode characteristics: commonly, the enzyme includes glucose oxidase, alcohol dehydrogenase and glucose dehydrogenase, the respective contents of which are from 0.5% to 25%;

4. Preparing the working electrodes according to the ingredient proportion of the reference electrodes: using the cyclic voltammetry of the electrochemical analyzer and the amperometric (using the variation of time and electric current) to find out the optimal potential;

5. Testing the working electrodes by using [Potash prus-siate, K₃Fe(CN)₆] and [Potassium Ferrocyanide. K₄Fe(CN)₆-3H₂O]: the testing operation is performed by using the electron transmit between the oxidation-reduction reaction of the [Potash prus-siate, K₃Fe(CN)₆] and [Potassium Ferrocyanide. K₄Fe(CN)₆-3H₂O] to check the repeatability and linearity.

C. Preparing biosensor chip: fixing the above components on the biosensor chip with the following steps: fixing the prepared enzyme within the electrode reaction zone, and then drying, covering and cutting the biosensor chip to finish the production of a biosensor chip sample.

D. Testing and setting parameter codes: testing the relevant parameters of the biosensor chip produced from the previous step and finding out matching parameters for the corresponding biosensor with the following steps: setting the group number of the sample tests for performing the sample test operations successively to find the their relationship, and comparing with the relationship found in the method for searching parameter codes of a biosensor to find out the corresponding parameter code, and then setting this parameter code in all the biosensor chips of this batch, if no corresponding parameter code can be fund, according to the experiment design or the Taguchi method in the statistics, the steps A-C will be repeated until the parameter code is found.

The method for producing a biosensor chip matching a biosensor can be used to produce the matching biosensor chips within the five zones with different concentrations (No. 1-10 are defined as the first zone, No. 11-20 are defined as the second zone, and the rest may be deduced by analogy) for the biosensor of the brand X, and the corresponding test result is shown in the following table:

| | Measurement | Measurement |
|---|---|---|
| | value of | value of self-made |
| No. | Brand X | biosensor chip |
| 1 | 98 | 95 |
| 2 | 98 | 98 |
| 3 | 84 | 96 |
| 4 | 84 | 95 |
| 5 | 94 | 97 |
| 6 | 94 | 94 |
| 7 | 94 | 97 |
| 8 | 94 | 99 |
| 9 | 96 | 94 |
| 10 | 96 | 94 |
| 11 | 142 | 148 |
| 12 | 142 | 146 |
| 13 | 144 | 152 |
| 14 | 144 | 152 |
| 15 | 143 | 150 |
| 16 | 143 | 150 |
| 17 | 146 | 147 |
| 18 | 146 | 153 |
| 19 | 128 | 146 |
| 20 | 128 | 148 |
| 21 | 210 | 218 |
| 22 | 210 | 222 |
| 23 | 218 | 224 |
| 24 | 218 | 222 |
| 25 | 220 | 234 |
| 26 | 220 | 223 |
| 27 | 219 | 226 |
| 28 | 219 | 226 |
| 29 | 214 | 228 |
| 30 | 214 | 231 |
| 31 | 303 | 309 |
| 32 | 303 | 311 |
| 33 | 314 | 307 |
| 34 | 314 | 314 |
| 35 | 315 | 309 |
| 36 | 315 | 301 |
| 37 | 315 | 311 |
| 38 | 315 | 314 |
| 39 | 320 | 301 |
| 40 | 320 | 307 |
| 41 | 474 | 467 |
| 42 | 474 | 480 |
| 43 | 489 | 459 |
| 44 | 489 | 465 |
| 45 | 411 | 479 |
| 46 | 411 | 475 |
| 47 | 492 | 478 |
| 48 | 492 | 468 |
| 49 | 495 | 480 |
| 50 | 495 | 482 |

When the above data is subjected to a static test, the correlation coefficient between the biosensor chip of the brand X and the self-made biosensor chip reaches 0.9924, which shows that they are highly correlated, and when a paired t test in statistics is performed, the difference probability is 0.1749, which shows that there is little obvious difference between the biosensor chip of the brand X and the self-made biosensor chip, thus proving the feasibility of the method for producing a biosensor chip matching a biosensor in accordance with the present invention.

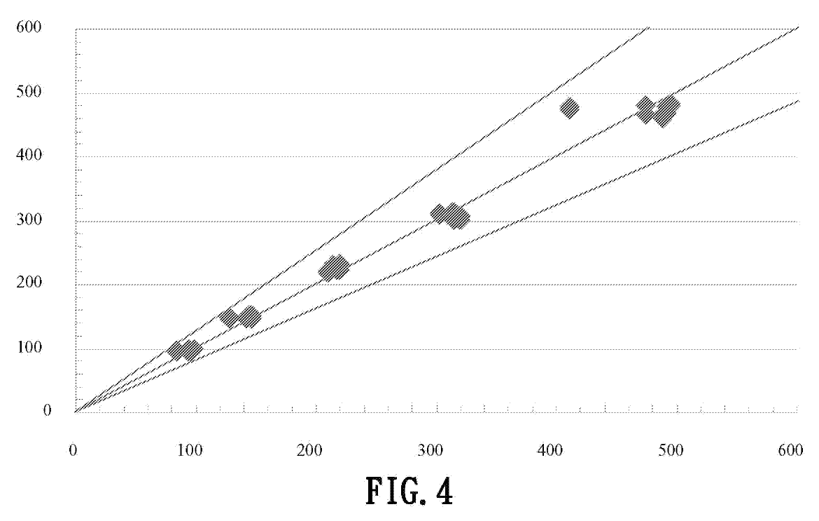

The relationship between the biosensor chips of the brand X and the self-made biosensor chips is shown FIG. 4, the transversal axis unit is expressed in mg/dl, and the longitudinal axis unit is also expressed in mg/dl. As known from FIG. 4, the relativity between the biosensor chips of the brand X and the self-made biosensor chips is very high, so that the method of the present invention can be used to produce matching biosensor chips for any specific biosensor effectively.

While we have shown and described various embodiments in accordance with the present invention, it is clear to those skilled in the art that further embodiments may be made without departing from the scope of the present invention.

What is claimed is:

1. A method for searching parameter codes of a biosensor comprising the steps of:
selecting parameter code: selecting any specific parameter code in the biosensor;
searching a relationship between the parameter codes: dividing a detection range into plural sections, and then performing a sample test to existing biosensor chips and using a forecast technology to find the relationship between the parameter codes; and
testing parameter code: selecting another parameter code in the biosensor, and repeating the above two steps until the parameter codes in the biosensor all have been tested or the specific parameter codes have been tested.

2. The method for searching parameter codes of a biosensor as claimed in claim 1, wherein a forecast technology used in the step of searching a relationship between the parameter codes is a linear regression, non-linear regression or non-parameter regression technology.

3. The method for searching parameter codes of a biosensor as claimed in claim 1, wherein a forecast technology used in the step of searching a relationship between the parameter codes is an evolutionary computation or soft computing technology

4. The method for searching parameter codes of a biosensor as claimed in claim 1, wherein a forecast technology used in the step of searching a relationship between the parameter codes is a grey theory technology.

5. A method for producing a biosensor chip matching a biosensor comprising the steps of:
searching parameter code relationship of a biosensor
preparing enzyme and electrode: preparing a buffer solution, adding interferent and enzyme in, and preparing working electrodes according to an ingredient proportion of the reference electrodes and testing the working electrodes to enable the oxidation-reduction between the working electrodes to be detected exactly to check repeatability and linearity;
preparing biosensor chip: fixing the above components on a biosensor chip; and
testing and setting parameter codes: testing relevant parameter codes of the biosensor chip produced from the previous step and finding out matching parameters for the biosensor.

6. The method for producing a biosensor chip matching a biosensor as claimed in claim 5, wherein the step of preparing enzyme and electrode includes: preparing a buffer solution to maintain a nearly constant PH according to the working electrodes; and then adding in anti-inteference to stabilize detection signals of the biosensor chips; adding in electronic mediator according to the parameter codes and electrode characteristics to utilize the electronic mediator to increase a electron transmit speed; preparing the enzyme according to the parameter codes of the biosensor and the electrode characteristics; preparing the working electrodes according the ingredient proportion of the reference electrodes to find out an optimal potential; and finally testing the working electrodes by using [Potash Prus-siate, K₃Fe(CN)₆] and [Potassium Ferrocyanide. K₄Fe(CN)₆-3H₂O].

7. The method for producing a biosensor chip matching a biosensor as claimed in claim 6, wherein the buffer solution in the step of preparing enzyme and electrode is prepared by using H₂C₈H₄O₄—KHC₈H₄O₄ and H₃BO₃—Na₂B₄O₇.

8. The method for producing a biosensor chip matching a biosensor as claimed in claim 6, wherein a PH value of the buffer solution in the step of preparing enzyme and electrode ranges from 3.6 to 8.0.

9. The method for producing a biosensor chip matching a biosensor as claimed in claim 6, wherein the anti-inteference in the step of preparing enzyme and electrode is Poly-N-Vinyl Pyrrolidone (PVP), Polyvinyl Alcohol (PVA) or Cellulose.

10. The method for producing a biosensor chip matching a biosensor as claimed in claim 6, wherein the content of the anti-inteference in the step of preparing enzyme and electrode ranges from 0.5% to 10%.

11. The method for producing a biosensor chip matching a biosensor as claimed in claim 6, wherein the enzyme in the step of preparing enzyme and electrode includes glucose oxidase, alcohol dehydrogenase and glucose dehydrogenase.

12. The method for producing a biosensor chip matching a biosensor as claimed in claim 6, wherein the content of each of the glucose oxidase, alcohol dehydrogenase and glucose dehydrogenase of the enzyme in the step of preparing enzyme and electrode ranges from 0.5% to 25%.

13. The method for producing a biosensor chip matching a biosensor as claimed in claim 6, wherein the step of preparing enzyme and electrode uses a cyclic voltammetry of electrochemical analyzer and an amperometric.

14. The method for producing a biosensor chip matching a biosensor as claimed in claim 5, wherein the step of preparing biosensor chip includes fixing the prepared enzyme within an electrode reaction zone, and then drying, covering and cutting the biosensor chip to finish a production of a biosensor chip sample.

15. The method for producing a biosensor chip matching a biosensor as claimed in claim 5, wherein the step of testing and setting parameter codes includes:
setting a sample test group number for performing the sample test operations successively to find their relationship, and comparing with the relationship found in the method for searching parameter codes of a biosensor to find out a corresponding parameter code, if no corresponding parameter code is fund, the previous steps will be repeated until the corresponding parameter code is found.

16. The method for producing a biosensor chip matching a biosensor as claimed in claim 5, wherein the step of testing and setting parameter codes adopts an experiment design or a Taguchi method in statistics to find the corresponding parameter code.
